(19) United States
(12) Patent Application Publication
(10) Pub. No.: US 2014/0103938 A1
(43) Pub. Date: Apr. 17, 2014

(54) SELF-REGULATING HEATER CABLE FAULT DETECTOR

(71) Applicant: MSX, Incorporated, South Bend, IN (US)

(72) Inventor: Thaddeus M. Jones, Bremen, IN (US)

(73) Assignee: MSX, Incorporated, South Bend, IN (US)

(21) Appl. No.: 14/053,158

(22) Filed: Oct. 14, 2013

Related U.S. Application Data
(60) Provisional application No. 61/713,051, filed on Oct. 12, 2012.

(51) Int. Cl. G01R 31/02

(52) U.S. Cl. CPC G01R 31/021
USPC 324/511

(57) ABSTRACT

A method of determining a condition of a heater cable, the method including the steps of providing an electrical voltage to the heater cable; and analyzing electrical signals generated in the heater cable to determine the condition of the heater cable.

### CROSS REFERENCE TO RELATED APPLICATIONS

This is a non-provisional application based upon U.S. provisional patent application Ser. No. 61/713,051, entitled “SELF-REGULATING HEATER CABLE FAULT DETECTOR”, filed Oct. 12, 2012, which is incorporated herein by reference.

### BACKGROUND OF THE INVENTION

1. Field of the Invention

The present invention relates to the detection of faults within a self-regulating heater cable. These heater cables are used in applications such as freeze protection and ice/snow melting from pavement, roofs, gutters, and antennae.

2. Description of the Related Art

The design and construction of self-regulating heater cable are well known. U.S. Pat. Nos. 4,624,990 and 4,545,926 describes various aspects of fluoropolymer composition, the material used in the heat generating core of self-regulating heater cable. The latter patent also shows typical temperature vs. resistivity characteristics. In the case of a heater application, this trait is used to have the heater effectively turn itself off when the desired temperature is reached. At cooler temperatures the heater core material allows more current to flow, thereby heating the cable and local environment.

In normal operation the electrically conductive carbon particles contained in the core polymer touch and produce heat, as represented in FIG. 2A. FIG. 2B shows the condition when warm particles are separated by the polymer's thermal expansion.

A self-regulating heater cable has a limited life. In one common failure mode the core polymer and its contents oxidize over time. The result is an overall higher electrical resistance and lower heat output. This effect is more pronounced with high temperatures and can be localized in a small section of the cable. One such localized failure mode is a poor electrical connection between the heater's core polymer and the bus power conductors. The greater electrical resistance produces a hot spot that degrades the core material and eventually results in a low power cold spot in the cable. Another failure mode is a loose jacket. The poor thermal conduction can produce a localized hot spot which also leads to a low power cold spot.

Self-regulating heater cables are also subject to other failure modes. During installation a cable may be kinked or crushed such that the insulation is damaged. Age, flexing, UV light, and other effects may also degrade the insulation. The cable is often constructed with a safety ground braid to provide mechanical protection and a safety ground path should the insulation layer fail.

Various safety protection devices are used with a self-regulating heater cable circuit. One is a common circuit breaker sized so that excessively high current in the cable is detected and interrupted. Another is a ground fault circuit that detects excessive leakage current from one of the AC power bus wires to ground. U.S. Pat. No. 5,710,408 describes a device that combines heater control and a ground fault interruption functions.

Various monitoring approaches have been used to determine or verify the proper operation of the self-regulating heater cable. One example is U.S. Pat. No. 5,818,012 which places a neon light bulb indicator at the far end of the cable. Other approaches monitor the voltage and current at one or both ends of the cable to attempt to detect abnormal conditions.

What is needed in the art is an efficient device and method of determining the condition of heater cable.

### SUMMARY OF THE INVENTION

The present invention relates to a method of monitoring a self-regulating heater cable.

As the carbon particles inside the heater cable react to temperature, some small amount of electrical arcing occurs as these particles alternately conduct and interrupt the heating current. See FIGS. 2A and 2B. This arcing produces some amount of electrical noise at a frequency significantly higher than the power line frequency. As the carbon particles oxidize, erode, or otherwise change, the characteristics of the electrical noise also changes. Analyzing the electrical noise provides a method to determine the condition of the heater cable.

An advantage of the present invention is it's a non-invasive approach. Changes within the cable produce changes in the characteristics in the electrical noise signal. There is no need to add extra wires or layers of special materials to the cable's construction to sense the health of the heater core.

Another advantage of the present invention is its ability to predict some types of cable failures. Self-regulating heater cables can degrade slowly. Sensing the degradation allows notice to be given well before the heater cable has completely failed.

### BRIEF DESCRIPTION OF THE DRAWINGS

The above-mentioned and other features and advantages of this invention, and the manner of attaining them, will become more apparent and the invention will be better understood by reference to the following description of an embodiment of the invention taken in conjunction with the accompanying drawings, wherein:

FIG. 1 shows a typical construction of a self-regulating heater cable;

FIG. 2A schematically shows a conceptual view of the conductive carbon particles contained within the self-regulating heater cable, with the plastic matrix containing the carbon particles being cold, allowing the particles to touch and be electrically conductive;

FIG. 2B schematically illustrates the same location of the heater cable when the plastic matrix is warm and the particles do not touch;

FIG. 3 is a schematic illustration of an embodiment of the present invention, showing each of the subsystems and their interconnections;

FIG. 4 shows an electrical schematic of one embodiment of the power line interface circuit;

FIG. 5 is a block diagram of one embodiment of the frequency spectrum analysis module; and

FIG. 6 is a block diagram of one embodiment of the control module.

Corresponding reference characters indicate corresponding parts throughout the several views. The exemplification set out herein illustrates an embodiment of the invention, in one form, and such exemplification is not to be construed as limiting the scope of the invention in any manner.

### DETAILED DESCRIPTION OF THE INVENTION

Referring now to the drawings, and more particularly to FIG. 1, there is shown a typical heating cable 17 having two power buss wires 11 surrounded by a fluoropolymer composition plastic matrix 12. The fluoropolymer plastic matrix 12 is surrounded by an electrical insulating layer 13, over which is placed a shield or a ground guard 14 for electrical and mechanical safety. A further insulating and protective outer jacket 15 is placed over the ground shield 14.

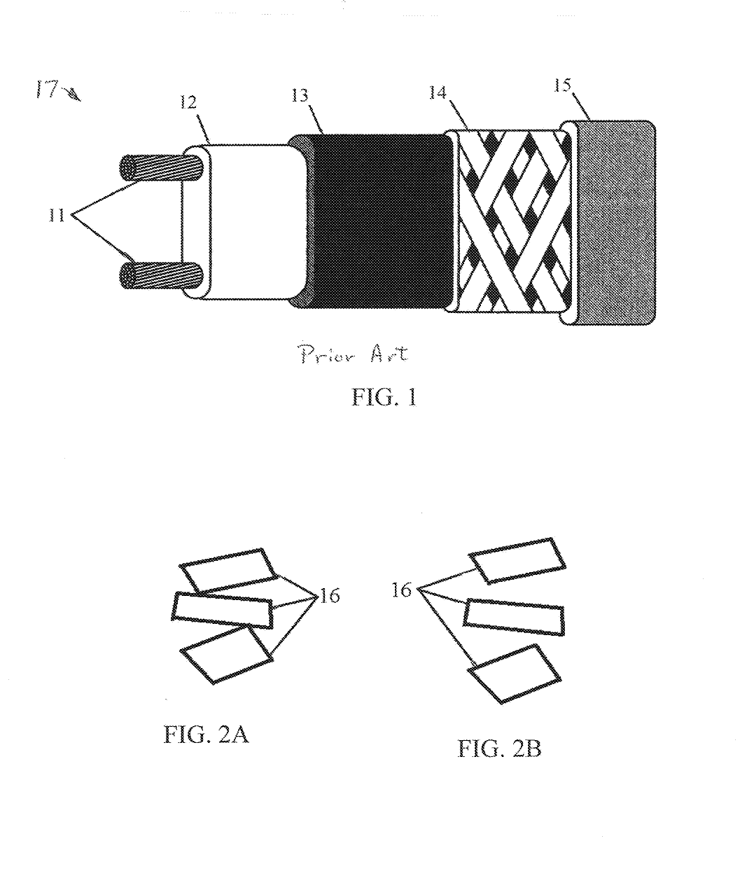

Now, additionally referring to FIGS. 2A and 2B, there is schematically shown a conceptual view of conductive carbon particles contained within heater cable 17. FIG. 2A schematically illustrates carbon particles 16 that are contained in the plastic matrix when plastic matrix 12 is cold, allowing carbon particles 16 to touch and be electrically conductive to thereby pass electrical current between wires 11. FIG. 2B schematically illustrates the same location of heater cable 17 when the plastic matrix is warm and particles 16 do not touch, thereby interrupting current flowing at this location between wires 11.

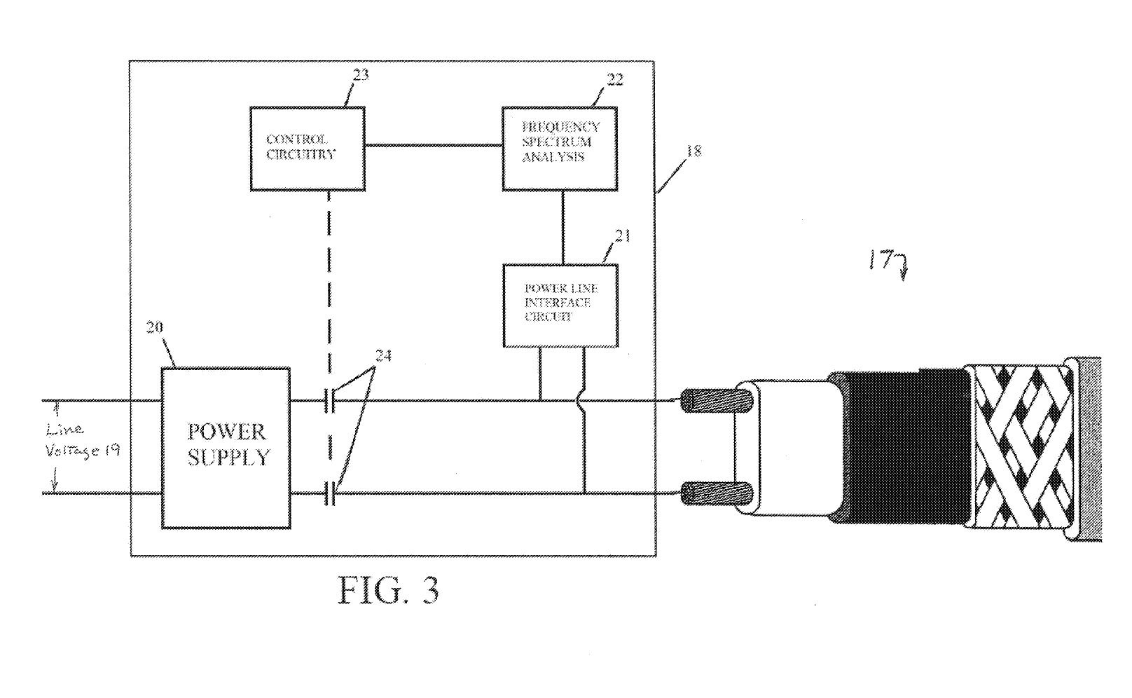

Now, additionally referring to FIG. 3, there is shown an overall view of an embodiment of a self-regulating heater cable fault detector 18 of the present invention. Fault detector 18 generally includes a power supply 20, a power line interface circuit 21, a frequency spectrum analysis module 22, control circuitry 23, and a contactor 24, connected to external self-regulating heater cable 17.

Where in this application the terms “control”, “controlling” or the like are used, it is to be understood that such terms may include the meaning of the terms “regulate”, “regulating”, etc. That is, such “control” may or may not include a feedback loop. Moreover, it is also to be understood, and it will be appreciated by those skilled in the art, that the methodology and logic of the present invention described herein may be carried our using any number of structural configurations such as electronic hardware, software, and/or firmware, or the like.

A line voltage 19 supplies power to system 18 including heater cable 17. Power supply 20 derives its power from the line voltage 19 and supplies all circuits with appropriate AC and DC operating voltages.

The fluoropolymer composition 12, sometimes referred to as the heater core matrix, contains electrically semi-conductive carbon granules 16 of a specific size and shape. When the cable is cool, the carbon granules touch one another and provide an electrically conductive path between power buss wires 11. This situation is represented in FIG. 2A. The carbon granules heat up in response to the electric current, and in turn heat the plastic matrix 12. As the fluoropolymer composition 12 heats it expands. This expansion pulls some of the carbon granules 16 apart, as represented in FIG. 2B. With no contact, the electric current cannot flow through those specific granules 16, allowing those granules 16 to cool. As fluoropolymer composition 12 cools it contracts and allows carbon granules 16 to touch once again, to thereby reestablish a conductive path and dissipate heat.

In the embodiment shown in FIG. 3 some of the electrical noise from arcing between carbon granules 16 within the heater cable 17 is removed from the power line by power line interface circuit 21. Interface circuit 21 blocks the majority of the low frequency AC power line signals, and passes the desired higher frequency signals from self-regulating heater cable 17 to frequency spectrum analysis module 22.

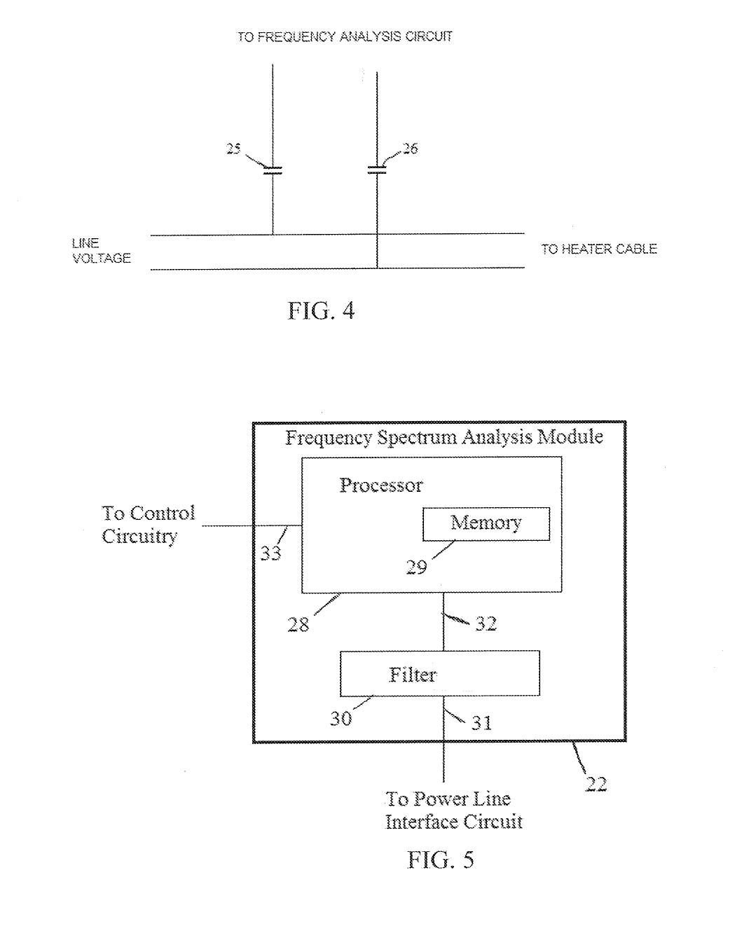

One embodiment of power line interface circuit 21, shown in FIG. 4, consists of two capacitors 25 and 26. The capacitors form a capacitive attenuator and when combined with load resistance from frequency spectrum analysis module 22 serve to form a high pass frequency filter. Capacitors 25 and 26 are sized primarily to attenuate line voltage 19 to a level that frequency spectrum analysis module 22 can tolerate. Secondarily capacitors 25 and 26 are sized for their desired high pass filter characteristics. In practice, values on the order of 1,000 pF are found to be acceptable. Note that capacitor 25 and capacitor 26 are not required to be the same value.

Power line interface circuit 21 is not limited to the embodiment shown in FIG. 4. One possible variation includes a transformer in the signal path. Inductively decoupling the signal from the line voltage 19 allows the advantage of electrical isolation between the frequency spectrum analysis module 22 and the input line voltage 19. Other embodiments of the power line interface 21 are possible as known by those skilled in the art.

The Frequency Spectrum Analysis Module 22 is shown in detail in FIG. 5. It consists of a processor module 28 with memory 29, and input filter(s) 30.

The purpose of the processor module 28 is to analyze the input signals that arrive from the power line interface circuit 21 via the optional filter circuit(s) 30 and signal paths 31 and 32. Signal paths 31 and 32 are typically electrically conductive wires or cable assemblies. The processor 28 analyzes the frequency content, amplitude, and/or other characteristics of the input signals. The processor may use one or more microprocessors, digital signal processors, gate arrays, discrete active and/or passive filters, or other devices known to those skilled in the art. The processor device may, but is not required to, include a memory 29 to record values of frequency, amplitude, and/or other characteristics of the input signal. Other information such as day and time may also be stored in memory 29.

Input filter 30 passes certain desired or reject certain undesired portions of the frequency spectrum of signals that arrive from power line interface circuit 21 by way of signal path 31. Filter 30 includes one or more active or passive filter circuits. Depending on the input characteristics and capabilities of processor 28, input filter 30 may not be required for proper operation of frequency spectrum analysis module 22. If filter 30 is not present, signal path 32 is also not present and signal path 31 extends from power line interface circuit 21 to processor 28.

As processor 28 detects the presence or absence of a desired or undesired signal from heater cable 17, various signals are sent to the control module 23 via signal path 33. These signals are typically related to, but not limited to, the presence or absence of various signals originating in the heater cable. Signal path 33, as with all signal paths discussed herein, may take the form of an electrically conductive path on a circuit board, a wire typically insulated, or a cable. Other options are also possible, such as a beam of light or a radio wave. The signal may be carried in an encoded fashion as is seen in communication protocols such as RS232, RS486, Ethernet, or CAN. Communication options other than those listed here are also possible; the current invention is not limited to the listed examples.

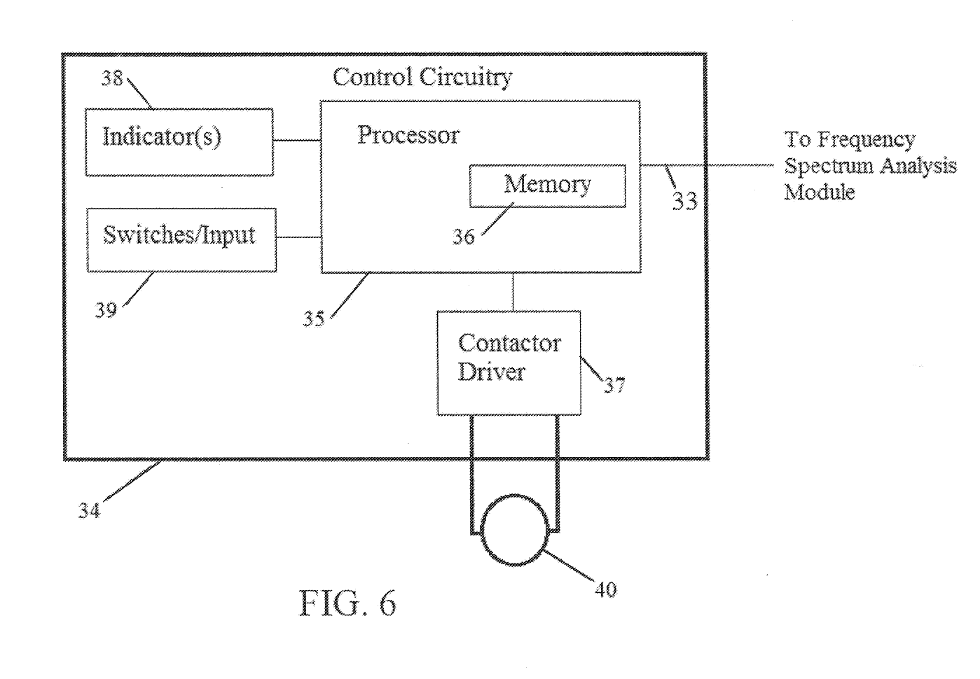

Control circuitry 23 is shown in detail in FIG. 6. It consists of a Processor 35 with optional memory 36, output devices such as indicators 38, input devices such as switches or sensors 39, and optional high power interface 37 to drive a relay contactor coil 40 or similar load.

The purpose of processor module 35 is to control the operation of heater cable monitoring system 18. Processor module 35 analyzes the input signals that arrive from frequency spectrum analysis module 22 by way of signal path 33, and from inputs 39. Software or other instructions may be placed in memory 36 to assist processor 35 in performing its tasks. Memory 36 may also be used to store working data such as current conditions or alarm set points.

Outputs may include, but are not limited to, a relay contactor 40 that removes power from the heater cable 17, by way of contacts 24, and/or various indicators 38 described below. Heater cable monitoring system 18 will remove electrical power from heater cable 17, when predefined criteria are met, such as the detection of a level of degradation of heater cable 17. Processor 35 may use one or more microprocessors, digital signal processors, gate arrays, discrete electronic components, or other devices known to those skilled in the art.

One or more indicators 38 may be used to announce certain desired or undesired conditions in the system. Indicators 38 may take the form of any combination of lights, buzzers, horns, or other attention attracting devices. Indicators 38 may also take the form of relay contacts, output voltage, or other ways of transferring data for remote announcement and/or recording.

One or more switches or other input device 39 may be used to control the operation of system 18. Input devices 39 may take the form of switches, potentiometers, or other human interface device. These human interface inputs may be accessible to the end user, or may be hidden or otherwise restricted from public use. Input device 39 may also take the form of a signal input, either analog as in the case of a remote sensor or digital as in the case of a remote command input. The function of any input can vary widely depending on system requirements and capabilities of processor 35.

It should be noted that indicators 38, and/or inputs 39 are also not required elements of heater cable fault detector system 18. Depending on system requirements, proper operation may be obtained without the use of indicators 38 and/or inputs 39.

Depending upon the capabilities of processors 28 and 35 and other factors, it may be possible and/or desirable to combine the functions of blocks 28 and 35 into one processor unit. Processors 28 and 35 can also be considered controllers 28 and 35, which may be carried out by any combination of software and hardware to carry out the functions of the present invention. The self-regulating heater cable fault detector described herein may be used in combination with other safety devices. Examples include but are not limited to a properly sized circuit breaker located on the power input cables, and/or a ground fault equipment protection (GFEP) circuit. The GFEP and current invention may share common parts such as the relay contactor and/or processors 28 and 35. The various safety devices monitor different aspects of the heater cable's operation for greater overall safety.

The self-regulating heater cable fault detector described herein may also be incorporated into existing designs of ice and snow melting equipment and controls. Some of these controls also include a built in GFEP circuit. Combining these several functions into one box offers convenience and economy for the end user.

It is also contemplated that one system 18 may be switched or multiplexed to detect the characteristics of several heater cables 17. Appropriate indicators 38 will then be used to alert operators of which heater cable 17 has a problem and the nature of the problem.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method of determining a condition of a heater cable, the method comprising the steps of:
providing an electrical voltage to the heater cable; and
analyzing electrical signals generated in the heater cable to determine the condition of the heater cable.

2. The method of claim 1, wherein said electrical signals are generated as a result of a change in at least one characteristic of carbon particles in the heater cable.

3. The method of claim 2, wherein said characteristic is indicative of a degradation of the heater cable.

4. The method of claim 2, wherein said electrical signals includes electrical noise caused by said change.

5. The method of claim 4, wherein said electrical noise has at least one frequency higher than a frequency of said electrical voltage.

6. The method of claim 5, wherein said at least one frequency of said electrical noise is significantly higher than said frequency of said electrical voltage.

7. The method of claim 1, wherein the method is carried out without adding either wires or layers to the heater cable.

8. The method of claim 1, further comprising the step of predicting at least one of degradation and failure of the cable dependent upon said electrical signals.

9. The method of claim 8, further comprising the step of sending an alert dependent upon said predicting step predicting one of said degradation and said failure of the heater cable.

10. The method of claim 8, further comprising the step of activating an indicator dependent upon said predicting step predicting one of said degradation and said failure of the heater cable.

11. A heater cable analyzer, comprising:
a frequency analyzer operatively connected to a heater cable having carbon particles therein; and
a controller in communication with said frequency analyzer, said controller being configured to carry out the steps of:
providing an electrical voltage to the heater cable; and
prompting said frequency analyzer to analyze electrical signals generated in the heater cable to determine the condition of the heater cable.

12. The heater cable analyzer of claim 11, wherein said electrical signals are generated as a result of a change in at least one characteristic of the carbon particles in the heater cable.

13. The heater cable analyzer of claim 12, wherein said characteristic is indicative of a degradation of the heater cable.

14. The heater cable analyzer of claim 12, wherein said electrical signals includes electrical noise caused by said change.

15. The heater cable analyzer of claim 14, wherein said electrical noise has at least one frequency higher than a frequency of said electrical voltage.

16. The heater cable analyzer of claim 15, wherein said at least one frequency of said electrical noise is significantly higher than said frequency of said electrical voltage.

17. The heater cable analyzer of claim 11, wherein the method is carried out without adding either wires or layers to the heater cable.

18. The heater cable analyzer of claim 11, wherein said controller is further configured to carry out the step of predicting at least one of degradation and failure of the cable dependent upon said electrical signals.

19. The heater cable analyzer of claim 18, wherein said controller is further configured to carry out the step of sending an alert dependent upon said predicting step predicting one of said degradation and said failure of the heater cable.

20. The heater cable analyzer of claim 18, wherein said controller is further configured to carry out the step of activating an indicator dependent upon said predicting step predicting one of said degradation and said failure of the heater cable.
